(19) United States
(12) Patent Application Publication
(10) Pub. No.: US 2022/0267891 A1
(43) Pub. Date: Aug. 25, 2022

(54) METHOD FOR DEPOSITING A RARE MATERIAL IN A THIN LAYER ON AN HOROLOGICAL OR JEWELLERY EXTERNAL PART AND EXTERNAL PART OBTAINED BY THIS METHOD

(71) Applicant: The Swatch Group Research and Development Ltd, Marin (CH)

(72) Inventors: Michel WILLEMIN, Preles (CH); Simon SPRINGER, Berne (CH); Loïc CURCHOD, Lausanne (CH)

(73) Assignee: The Swatch Group Research and Development Ltd, Marin (CH)

(21) Appl. No.: 17/572,991

(22) Filed: Jan. 11, 2022

(30) Foreign Application Priority Data
Feb. 22, 2021 (EP) 21158411.5

(51) Int. Cl. C23C 14/34; A44C 27/00; G04B 47/04; C23C 14/58; C23C 14/14

(52) U.S. Cl. CPC C23C 14/3414; A44C 27/006; G04B 47/042; C23C 14/5886; C23C 14/14

(57) ABSTRACT

A method for depositing a rare material in a thin layer at the surface of an horological or jewellery external part includes providing a rough part of rare material, shaping the rough part of rare material so that it is adapted to be used as a target part for a PVD method, depositing material of the target part at the surface of a substrate consisting of an horological or jewellery eternal part by a PVD method so as to cover the external part.

### TECHNICAL FIELD OF THE INVENTION

The invention lies in the field of horology and jewellery.

More particularly, the invention relates to a method for depositing a rare material in a thin layer on an horological or jewellery external part and a timepiece or piece of jewellery obtained by this method.

The terms “rare material” designate, in the present text, any material that is very rare, or even unique, by its origin, its history, its composition, etc. which has in particular because of this a high pecuniary and/or emotional value. Moreover, the present text is about a rare material in solid form at ambient temperature.

For example, rare materials in the sense of the present invention can be materials of extra-terrestrial origin, for example coming from meteorites or from samples collected during space missions, materials coming from relics, from locations or from objects related to a particular history, for example, fragments of wrecks of ships or of space rockets, objects having belonged to historical figures, etc.

### TECHNOLOGICAL BACKGROUND

In the field of horology and of jewellery, it is routine to use noble materials and rare materials to carry out decorative functions.

In the present text, “noble materials” means any precious material, for example precious metals, such as gold or silver.

For example, in the field of horology or of jewellery, it is known to integrate inserts into external parts, such as elements of the wristlet or of the case of a watch, or of the piece of jewellery, or to entirely create these external parts from noble materials and rare materials.

More specifically, it is known to integrate rare materials such as pieces of meteorites or of wrecks in forms of more or less large elements in the dial, the bezel or the middle of a watch.

These pieces are collected, for example in the form of more or less thin slices, in an original, rough, part made of rare material and shaped so as to correspond to the dimensions of an insert or of the external part that they are intended to form. More specifically, these parts are generally collected, then shaped by mechanical machining.

With the use of these collecting and shaping methods, the original appearance of the rare material is generally preserved, but a large quantity of material of the original part is consumed. In particular, these collecting and shaping methods lead to the generation of chips and of trimmings of the rare material that do not satisfy the requirements of size and/or appearance allowing them to be used as an insert in external parts or as an external part.

The original parts of rare material being by definition very rare and costly, the need to limit as much as possible these losses of material is understood.

Moreover, the integration of rare material at the surface of external parts generally poses problems of mechanical strength of the assembly over time. Horologists are thus often forced to add fastening brackets or other mechanical elements to maintain the rare material in position on the external parts, which is capable of affecting the reliability, the appearance, the weight and the manufacturing cost of the timepiece or piece of jewellery integrating such an external part.

### SUMMARY OF THE INVENTION

The invention resolves the aforementioned disadvantages by proposing a solution allowing to cover with a rare, or even unique, material an horological or jewellery external part while avoiding, or considerably limiting, the losses of said rare material during the manufacturing of said external part.

One of the main advantages of the present invention is the savings of the rare material that it allows, insofar as the quantity of rare material consumed corresponds substantially to the quantity necessary to cover the external part.

It should be noted that the present invention does not have the goal of restoring an appearance faithful to that of the original part of rare material, but that it aims to use all, or a large part, of the atoms of the part of rare material so as to eliminate, or greatly reduce, the losses of said part.

For this purpose, the present invention relates to a method for depositing a rare material in a thin layer at the surface of an horological or jewellery external part including the following steps:
providing a rough part made of rare material chosen from materials of extra-terrestrial origin, for example coming from meteorites or from samples collected during space missions, materials coming from relics, rare materials coming from locations or from objects related to a particular history, for example, fragments of wrecks of ships or of space rockets, objects having belonged to historical figures;
shaping the rough part of rare material so as to obtain a target part usable by a physical vapour deposition method, in particular by cathode sputtering;
depositing material of the target part on the surface of a substrate consisting of an horological or jewellery eternal part by the implementation of a physical vapour deposition method, in particular by cathode sputtering of said target, so as to cover the surface of said external part.

One of the main advantages of this method lies in the fact that the rare material forming the target part can be reused once the method has been completed, in the production of a new part. Therefore, substantial savings of rare material are achieved. Thus, the unit cost of manufacturing the horological or jewellery external parts is considerably reduced.

Moreover, very little rare material is necessary to cover the external part. Furthermore, it is possible, via the method according to the invention, to use any residue or any trimmings of rare material, which further participates in reducing the unit cost of manufacturing the horological or jewellery external parts.

Indeed, these residues or trimmings of rare material can be, according to their nature, melted, powdered or compressed and be shaped to obtain a new target part.

These features thus make possible the industrial production of small or medium series of horological or jewellery parts including rare material, whereas in the current state of the technique the production is manufactured by units in an artisanal manner.

Moreover, the method according to the invention allows to ensure an excellent mechanical strength of the rare material on the external part, contrary to the solutions of the prior art.

Moreover, physical vapour deposition methods have the advantage of being effective without knowing the exact composition of the target part, and thus of the rare material, which is often the case when the latter is not analysed for this purpose.

Finally, the chemical composition of the thin layer is representative of that of the target part, just like its homogeneity.

In specific embodiments, the invention can further include one or more of the following features, taken alone or according to all the technically possible combinations.

In specific embodiments, the shaping step involves forming the target part in the form of a disc or in the form of a powdered material, that is to say a material in the form of a powder, or in the form of granules.

In specific embodiments, the rare material is associated with at least one other material, called “auxiliary material”, so that the layer deposited on the horological or jewellery external part results from the combination of said rare material and of the at least one auxiliary material.

In specific embodiments, the auxiliary material is chosen from gold, silver, platinum, palladium, rhodium, or an alloy of one or more of these metals, or a ceramic or a crystal.

In specific embodiments, the shaping step comprises an operation of shaping at least one second target part made from the auxiliary material, and with which during the deposition step, the deposition of rare material and of the auxiliary material on the horological or jewellery external part is carried out simultaneously.

In specific embodiments, the shaping step includes an operation of forming the auxiliary material in the form of a disc including a plurality of housings receiving in cooperation of shape inserts made from the rare material, so as to form a single target part.

In specific embodiments, in the shaping step, a powder or pellets made from a rare material are integrated into a matrix made from the auxiliary material.

In specific embodiments, the target part can advantageously be shaped, during the shaping step, by the fastening of particles of powder, of pellets, of chips or other residues of rare material onto a support part, for example in the form of a disc, made from the auxiliary material, via a material consisting for example of a suitable glue, such as an epoxy glue, or of indium.

In specific embodiments, the step of depositing material is carried out by cathode sputtering.

In specific embodiments, the step of depositing material is carried out by a direct evaporation method, in particular by thermal evaporation or by electron beam or laser bombardment.

In specific embodiments, the method according to the invention comprises a preliminary step of surface preparation before the step of depositing material of the target part.

In specific embodiments, the preliminary step involves depositing an adhesion sublayer at the surface of the external part and/or carrying out a structuring of the surface either to improve the adhesion or to simulate the structure of the initial part made of rare material.

In specific embodiments, the method according to the invention comprises a final step of treatment of the surface of the thin layer deposited after the deposition step.

In specific embodiments, the final step comprises a cellulose varnishing, a deposition of a transparent thin layer by a physical vapour deposition method, a deposition of a transparent atomic thin layer, or a deposition of a transparent thin layer by a chemical vapour deposition method.

According to another object, the present invention relates to an horological or jewellery external part including a thin layer of rare material deposited by a deposition method as described above.

### BRIEF DESCRIPTION OF THE DRAWINGS

Other features and advantages of the invention will appear upon reading the following detailed description given as an example that is in no way limiting, in reference to the appended drawings in which:

FIG. 1 shows a flowchart illustrating steps of a method for depositing a rare material in a thin layer on the surface of an horological or jewellery external part according to an embodiment of the invention.

### DETAILED DESCRIPTION OF THE INVENTION

The present invention relates to a method for depositing a rare material in a thin layer on the surface of an horological or jewellery external part. Advantageously, the present invention can also apply to any fashion item, for example from glasses manufacturing.

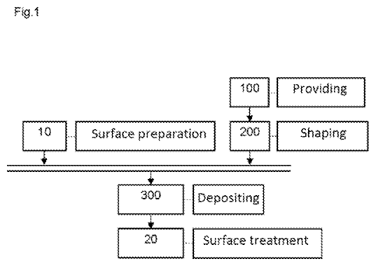

As shown by the flowchart of FIG. 1, the method according to the invention includes a first step of providing 100 a rough part of rare material, called hereinafter “rare material blank”. This step is followed by a step of shaping 200 said rare material blank so that it is adapted to be used as a target part for a method for depositing in a thin layer via a physical vapour deposition method, also known by the acronym PVD. A step of depositing 300 material of the shaped target part, on a substrate by a physical vapour deposition method, follows, said substrate consisting in the present invention of an horological or jewellery external part, implemented so as to cover said external part.

The rare material corresponds here to any very rare, or even unique, material, in particular because of its origin, its history, its composition, and which has in particular because of this a high pecuniary and/or emotional value. It is for example chosen, in the present invention, according to the appearance of the finished external part, that is to say once the thin layer of rare material is deposited, that it is desired to obtain. Moreover, the rare material can also be chosen according to the technical characteristics of the material forming it in order to confer certain technical properties on the finished external part.

Once the step of providing 100 the rare material has been completed, it is necessary to prepare the rare material blank, during the step of shaping 200, so as to obtain a target part comprising said rare material to implement a physical vapour deposition method. Such a method for depositing a thin layer on a substrate is described as such later in the description.

The carrying out of this step of shaping 200 depends in particular on the nature of the material forming the rare material blank.

In particular, as a non-limiting example, if the rare material blank provided is made of metal material, for example if it comes from a residue of a wreck, it is advantageous to shape it so that the target part takes the shape of a disc, for example having a radius of several centimetres and a thickness of several millimetres. For this purpose, during the step of shaping 200, the target part can be obtained by machining of the rare material blank, and optionally by melting and moulding if the rare material blank provided is in the form of a set of residues or of particles of rare material, or optionally by compression of a powder and sintering.

The moulding techniques used are adapted to the nature of the rare material blank. For example, it is possible to create the target part by sintering, by compression, by moulding a pouring of a molten material, etc.

Alternatively, if the rare material blank is made of a mineral material, for example a meteorite residue, it is advantageous for the target part resulting from the operation of shaping 200 to take the form of a powdered material, for example the form of a powder, or of pellets. For this purpose, during the step of shaping 200, the rare material blank can be ground.

Advantageously, according to the nature of the material forming the rare material blank, during the step of shaping 200, the latter is entirely ground, or it is machined and the chips, trimmings or other residues are melted and cast to form a target part. It is understood here that the method according to the present invention allows to avoid the losses of rare material insofar as the entirety of the rare material blank can be reused to produce new target parts.

It should be noted here that the step of shaping 200 can also involve forming the part in the form of a cylinder, of a wire, or in any other shape suitable for the target part resulting from this step to be able to be used in the step of deposition 300.

The type of method for depositing a thin layer used during the step of deposition 300 in the method according to the invention in particular depends on the carrying out of the step of shaping 200. In particular, according to whether the target part is in the form respectively of a disc or of a powdered material or of pellets, methods for depositing a thin layer respectively by spraying or by evaporation are preferred.

More particularly, the step of depositing 300 material of the target part involves carrying out in a reaction chamber formed by a closed chamber in which the atmosphere is controlled an operation involving vaporising atoms of the target part, then driving them in order for them to be deposited on the surface of a substrate, in this case on the external part, so as to form a thin layer of rare material on said substrate.

In an alternative embodiment of the step of deposition 300, the method for depositing a thin layer is carried out by cathode or arc sputtering, by laser beam or by ion beams.

In the embodiment of the present invention, the method for depositing a thin layer by cathode sputtering is preferred, insofar as it allows the deposition of a thin layer on a substrate having complex shapes in a simple and rapid manner, potentially without it being necessary to change the position of said substrate to obtain the deposition of a thin layer in a homogenous manner on the entirety of its surface.

This alternative embodiment is used when the target part is formed in the form of a disc, with or without auxiliary material as defined below.

In another alternative embodiment of the step of deposition 300, the method for depositing a thin layer is carried out by thermal evaporation, in particular at low pressure. The evaporation of the rare material of the target part is thus obtained under vacuum by Joule effect, by heat induction, by bombardment of a beam of ions or of electrons, by electric arc or by laser beam.

This alternative embodiment is used when the target part is formed in the form of a disc having reduced dimensions or in the form of a powdered material, that is to say in the form of a powder, or in the form of granules.

It should be noted that these methods are known as such to a person skilled in the art, and used in uses other than that described in the present text.

It can be particularly advantageous that in the medium of the chamber reagent gases are added in order to promote the deposition of the thin layer on the external part.

In an alternative embodiment of the invention, the rare material is associated with at least one other material, called “auxiliary material” in the rest of the text, so that the layer deposited on the horological or jewellery external part results from the combination of said rare material and of the at least one auxiliary material.

For this purpose, the step of shaping 200 can include an operation of shaping at least one second target part made from the auxiliary material, the latter being different than that forming the rare material blank.

For example, the auxiliary material can be a noble material such as a noble metal like gold, silver, platinum, palladium, rhodium, or an alloy of one or more of these metals. The auxiliary material can also be a ceramic material or a crystal.

Moreover, in this alternative embodiment of the invention, during the step of deposition 300, the deposition of rare material and of the material of the at least one second target part on the horological or jewellery external part is carried out simultaneously by the physical vapour deposition method, in the same chamber.

Advantageously, the auxiliary material and its quantity relative to the quantity of rare material deposited in a thin layer are chosen according to the desired appearance and/or according to the desired mechanical characteristics of said thin layer. The desired mechanical characteristics are represented in particular by the resistance to mechanical stresses or to corrosion of the external part at the end of the method according to the invention.

Alternatively, in another alternative embodiment of the method according to the invention, in which the rare material is also associated with at least one other material, the step of shaping 200 includes an operation of forming an auxiliary material, in the shape of a disc including a plurality of housings. The housings are advantageously provided to receive in cooperation of shape, for example by tight fitting, inserts made from the rare material and fastened in the housings of the disc of auxiliary material by setting or brazing or gluing, so that a single target part is formed by the particular arrangement of the rare material and of the other material.

The inserts can be composed of rare material sintered, compressed, moulded, machined, or shaped by any other means within the reach of a person skilled in the art.

The housings, and consequently the inserts of material, are arranged in such a way as to be regularly distributed circularly. More generally, the housings and inserts are arranged in the disc so as to correspond to the erosion track of the target part, also known by the name “racetrack” to a person skilled in the art.

Also alternatively, in the step of shaping 200, a powder, pellets, chips or other residues of rare material can be integrated into a matrix made from the auxiliary material.

Finally, also alternatively, the target part can advantageously be shaped, during the step of shaping 200, by the fastening of particles of powder, of pellets, of chips or other residues of rare material onto a support part, for example in the form of a disc, made from the auxiliary material, via a material consisting for example of a suitable glue, such as an epoxy glue, or of indium.

This feature allows to maximise the use of the rare material during the step of deposition 300.

Moreover, via the features of this alternative embodiment, it is possible to save even more rare material since only a small quantity is necessary to cover an external part with a thin layer.

Thus, during the step of deposition 300, the elements forming the target part, that is to say, the rare material and the auxiliary material, are deposited simultaneously and mix to form a thin layer of a new material resulting from this mixture, on the surface of the horological or jewellery external part.

According to the chosen proportion of rare material in the target part, the housings of the disc can have more or less large dimensions and/or the housings can be more or less numerous in the disc, so as to vary the size of the inserts and/or their number according to the desired quantity of rare material in the thin layer deposited on the surface of the external part.

It should be noted that the disc can be formed from a rare material and the inserts made from auxiliary material, even though this solution is not the most judicious given the cost of the auxiliary material and that of the rare material.

Also alternatively, during the step of shaping 200, the rare material can be doped or alloyed with suitable materials, for example metals or minerals, to confer onto it desired technical characteristics. The target part is thus, after alloying or doping, formed in the form of a disc.

For example, it is possible to melt a target from fine gold and extracts of a rare material coming for example from a part made of copper or brass or bronze coming from a famous wreck, or from mineral particles coming from a meteorite or from a sample collected during a space mission, in order to create a target made of alloy that is both noble and rare since it contains material coming from said part of a wreck or from said extra-terrestrial source, respectively.

Also alternatively, during the step of shaping 200, the rare material formed in powdered, or granule, form can be mixed with a powder of an auxiliary material, metal or mineral. The latter is chosen for its mechanical properties or for the appearance that it can confer on the external part once the step of deposition 300 has been carried out.

In another alternative embodiment of the invention, the physical vapour deposition method can also be implemented in a reactive atmosphere configured to modify the composition of the layer deposited in order to increase its mechanical properties and/or its appearance.

For example, the atmosphere can be configured so as to be oxidising, nitriding, carbonising, or it can be adapted to dope the rare material and/or the auxiliary material.

The method according to the present invention can include a preliminary step 10 of preparing the surface of the horological or jewellery external part by surface treatment of the external part, before the step of deposition 300. This preliminary step 10 can involve a surface texturing on the micro or macroscopic scale, for example to reproduce a structure typical of the rare material blank, for example of a meteorite, and/or to improve the adhesion, or by the activation of the surface by plasma.

More particularly, it is possible during the preliminary step 10 to deposit an adhesion sublayer allowing to improve the fastening of the thin layer to the external part surface. For example, the sublayer can be made from titanium, from aluminium or from chromium, in the case in which the external part is made from a ceramic material.

The method according to the present invention can also or alternatively include a final step 20 of treatment of the surface of the thin layer deposited, this step having the goal of protecting said thin layer from corrosion or from tarnishing for example. For example, the final step 20 comprises a cellulose varnishing, a deposition of a transparent thin layer by a physical vapour deposition method (known by the acronym PVD), a deposition of a transparent atomic thin layer by an ALD method (for “atomic layer deposition”), or a deposition of a transparent thin layer by a chemical vapour deposition method (known by the acronym CVD), etc.

Finally, another object of the present invention relates to an horological or jewellery external part including a thin layer of rare material deposited by the deposition method described above.

1. A method for depositing a rare material in solid form at ambient temperature, in a thin layer at the surface of an horological or jewellery external part, the method comprising the following steps:
providing a rough part of rare material,
shaping the rough part of rare material so as to obtain a target part,
depositing material of the target part on the surface of a substrate consisting of an horological or jewellery eternal part by the implementation of a physical vapour deposition method, so as to cover the surface of said external part,
wherein the step of shaping comprises an operation of shaping at least one second target part made from another material called “auxiliary material”, and wherein during the step of deposition, the deposition of rare material and of the auxiliary material on the horological or jewellery external part is carried out simultaneously.

2. The method according to claim 1, wherein the step of shaping involves forming the part in the form of a disc, in the form of a powdered material or in the form of granules.

3. The method according to claim 1, wherein the rare material is associated with at least one other material, called “auxiliary material”, so that the layer deposited on the horological or jewellery external part results from the combination of said rare material and of the at least one auxiliary material.

4. The method according to claim 3, wherein the auxiliary material is chosen from gold, silver, platinum, palladium, rhodium, or an alloy of one or more of these metals, or a ceramic or a crystal.

5. The method according to claim 3, wherein the step of shaping comprises an operation of forming the auxiliary material in the form of a disc including a plurality of housings receiving in cooperation of shape inserts made from the rare material, so as to form a single target part.

6. The method according to claim 3, wherein in the step of shaping, a powder or pellets made from a rare material are integrated into a matrix made from the auxiliary material.

7. The method according to claim 3, wherein during the step of shaping, the target part is shaped by the fastening of particles of powder, of pellets, of chips of rare material onto a support part made from the auxiliary material, via a material consisting for example of a suitable glue or of indium.

8. The method according to claim 1, wherein the step of depositing material is carried out by cathode sputtering.

9. The method according to claim 1, wherein the step of depositing material is carried out by a direct evaporation method.

10. The method according to claim 1, comprising a preliminary step of surface preparation before the step of depositing material of the target part.

11. The method according to claim 10, wherein the preliminary step involves depositing an adhesion sublayer on the surface of the external part.

12. The method according to claim 10, wherein the preliminary step involves carrying out a structuring of the surface of the external part to improve the adhesion or to simulate the structure of the initial part made of rare material.

13. The method according to claim 1, comprising a final step of treatment of the surface of the thin layer deposited after the step of deposition.

14. The method according to claim 13, wherein the final step comprises a cellulose varnishing, a deposition of a transparent thin layer by a physical vapour deposition method, a deposition of a transparent atomic thin layer, or a deposition of a transparent thin layer by a chemical vapour deposition method.

15. A horological or jewellery external part comprises a thin layer of rare material deposited by a deposition method according to claim 1.
